(19) United States
(12) Patent Application Publication
(10) Pub. No.: US 2016/0095256 A1
(43) Pub. Date: Mar. 31, 2016

(54) HEAT DISSIPATION MODULE

(71) Applicant: Subtron Technology Co., Ltd., Hsinchu County (TW)

(72) Inventor: Ching-Sheng Chen, Hsinchu County (TW)

(21) Appl. No.: 14/670,434

(22) Filed: Mar. 27, 2015

(30) Foreign Application Priority Data
Sep. 30, 2014 (TW) 103133943

(51) Int. Cl. H05K 7/20; F28D 15/02

(52) U.S. Cl. CPC H05K 7/20418; H05K 7/20263; H05K 7/2029; H05K 7/20336; F28D 15/0275

(57) ABSTRACT

A heat dissipation module includes a hollow housing, a plurality of heat dissipation fins and heat dissipation liquid. The hollow housing includes a chamber, a side surface, a top surface and a bottom surface opposite to the top surface. The side surface is connected to the top surface and the bottom surface. The heat dissipation fins are disposed on the side surface. The heat dissipation liquid is contained within the chamber, and a specific heat of the heat dissipation liquid is substantially greater than or equal to 1 cal/g° C.

### CROSS-REFERENCE TO RELATED APPLICATION

This application claims the priority benefit of Taiwan application serial no. 103133943, filed on Sep. 30, 2014. The entirety of the above-mentioned patent application is hereby incorporated by reference herein and made a part of this specification.

### BACKGROUND OF THE INVENTION

1. Field of the Invention

The invention relates to a heat dissipation module, and more particularly to a heat dissipation module having multiple heat dissipation paths.

2. Description of Related Art

With the prosperous development of electronic technology, new electronic products successively appear on the market to satisfy the needs of consumers. Currently, in electronic devices having higher thermal power, such as a central processing unit (CPU), a memory module, a graphics processing unit (GPU) and a chipset, an additional heat dissipation module is usually provided to remove excessive thermal energy from the electronic device, so as to prevent a temperature of the operating electronic device from going beyond the maximum temperature of normal operation thereof.

For instance, when emitting light having high brightness, a light-emitting diode (LED) chip generates massive thermal energy. If the thermal energy cannot be effused but rather keeps accumulating within the LED, a temperature of the LED keeps rising. Thereby, due to overheating, the LED may have brightness decay and shortened service life, or even permanent damage in severe cases. Therefore, current light-source apparatus adopting LED generally is provided with a heat sink to dissipate the heat in the LED.

However, when the brightness provided by the LED is higher, the light-source apparatus needs to have more heat sinks to dissipate the heat in the LED. Thus, such light-source apparatus requires sufficient space to accommodate for a large number of heat sinks, and a fabricating cost thereof is higher.

### SUMMARY OF THE INVENTION

The invention is directed to a heat dissipation module having excellent heat dissipation efficiency.

A heat dissipation module of the invention includes a hollow housing, a plurality of heat dissipation fins and heat dissipation liquid. The hollow housing includes a chamber, a side surface, a top surface and a bottom surface opposite to the top surface. The side surface is connected to the top surface and the bottom surface. The heat dissipation fins are disposed on the side surface. The heat dissipation liquid is contained within the chamber, and a specific heat of the heat dissipation liquid is substantially greater than or equal to 1 cal/g° C.

According to an embodiment of the invention, the chamber is a sealing chamber.

According to an embodiment of the invention, each of the heat dissipation fins is a hollow heat dissipation fin having a hollow portion. The chamber connects the hollow portions, and the heat dissipation liquid is contained within the chamber and the hollow portions.

According to an embodiment of the invention, a thermal conductivity of the hollow housing is greater than or equal to 230 W/mK.

According to an embodiment of the invention, the heat dissipation module is attached to a heat-generating device via the bottom surface.

According to an embodiment of the invention, each of the heat dissipation fins further includes a bending portion. Each of the heat dissipation fins is extended along a direction parallel to the bottom surface and bended at the bending portion to be extended toward the bottom surface.

According to an embodiment of the invention, the heat dissipation module further includes a heat dissipation fin set that is disposed on the top surface and thermally coupled with the hollow housing.

According to an embodiment of the invention, the heat dissipation fin set covers the chamber.

According to an embodiment of the invention, the heat dissipation module further includes a vapor chamber, disposed between the heat dissipation fin set and the hollow housing and thermally coupled therewith. The vapor chamber includes a vacuum chamber and a phase-transition medium. An inner wall of the vacuum chamber has a plurality of micro-structures. The phase-transition medium is contained within the vacuum chamber and is configured to perform liquid-gas phase transition in the vacuum chamber.

According to an embodiment of the invention, the heat dissipation module further includes a heat pipe disposed between the heat dissipation fin set and the hollow housing and thermally coupled therewith.

Based on the above, the heat dissipation module of the invention has the hollow housing that is highly thermal conductive for containing the heat dissipation liquid having a high specific heat (which specific heat is substantially greater than or equal to 1 cal/g° C.), and a plurality of heat dissipation fins are disposed on the side surface of the hollow housing. Thereby, by attaching the heat dissipation module to a heat-generating device, the heat dissipation module conducts the thermal energy of the heat-generating device to external environment by means of the high conduction characteristic of the hollow housing. In addition, the area of heat exchange is increased by means of the heat dissipation fins so that the heat dissipation liquid having high specific heat contained within the hollow housing is able to lower the temperature of the hollow housing and the heat-generating device. Therefore, the invention indeed has excellent heat dissipation effects.

To make the above features and advantages of the invention more comprehensible, several embodiments accompanied with drawings are described in detail as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view of a heat dissipation module according to an embodiment of the invention.

FIG. 2 is a schematic view of a heat dissipation module according to another embodiment of the invention.

FIG. 3 is a schematic view of a heat dissipation module according to another embodiment of the invention.

FIG. 4 is a schematic view of a heat dissipation module according to another embodiment of the invention.

FIG. 5 is a schematic view of a heat dissipation module according to another embodiment of the invention.

FIG. 6 is a schematic view of a heat dissipation module according to another embodiment of the invention.

### DESCRIPTION OF EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. As such, the directional terminology is used for purposes of illustration and is in no way limiting. Furthermore, in the following embodiments, the same or similar components adopt the same or similar numerals.

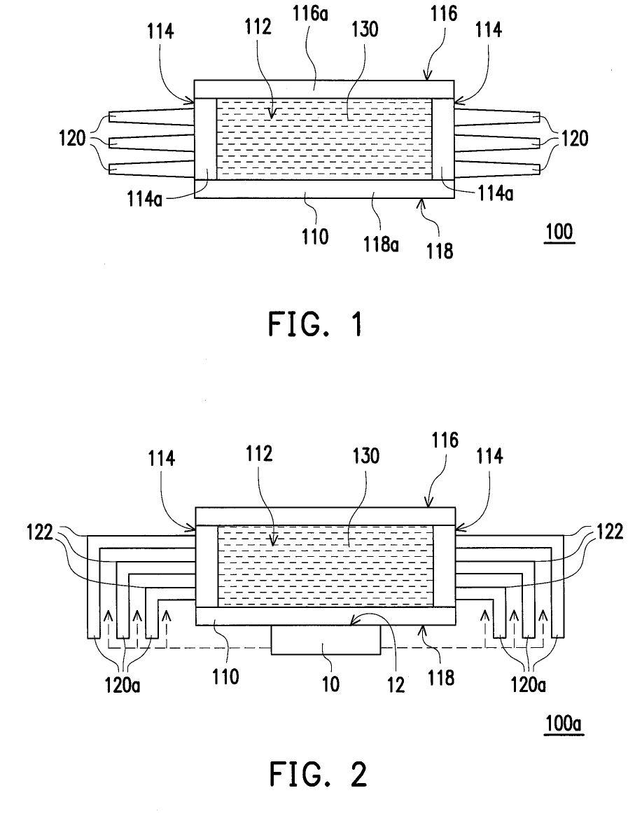

FIG. 1 is a schematic view of a heat dissipation module according to an embodiment of the invention. Referring to FIG. 1, a heat dissipation module 100 is adapted for being attached to, for example, a contact surface of a heat-generating device to dissipate the heat generated by the heat-generating device, and the heat dissipation module 100 includes a hollow housing 110, a plurality of heat dissipation fins 120 and heat dissipation liquid 130. The hollow housing 110 includes a chamber 112, a side surface 114, an upper surface 116 and a lower surface 118 opposite to the upper surface 116, wherein the side surface 114 is connected to the upper surface 116 and the lower surface 118. More specifically, the hollow housing 110 may, as shown in FIG. 1, include an upper component 116a, a lower component 118a and a side component 114a to compose this hollow housing 110. Herein, the upper component 116a may be, for example, a top plate, and the upper surface 116 is an outer surface of the upper component 116a; the lower component 118a may be, for example, a bottom plate, and the lower surface 118 is an outer surface of the lower component 118a. Similarly, the side component 114a may be a side wall, and the side surface 114 may be an outer surface of the side component 114a. It is for sure that this embodiment is merely an example and is not used for limiting the invention. The heat dissipation fins 120 may, for example, be disposed around the side surface 114, and the heat dissipation liquid 130 is contained within the chamber 112, wherein a specific heat of the heat dissipation liquid 130 is substantially greater than or equal to 1 cal/g° C. In this embodiment, the chamber 112 of the hollow housing 110 may be a closed chamber, and the heat dissipation liquid 130 may be water and is contained within this closed chamber 112. It is for sure that this embodiment is merely an example, and the invention does not limit on the types of the heat dissipation liquid 130.

Furthermore, the hollow housing 110 has the characteristic of high conduction, and a thermal conductivity thereof is substantially greater than or equal to 230 W/mK. In this embodiment, a material of the hollow housing 110 may be copper, aluminum or other materials having a thermal conductivity greater than or equal to 230 W/mK. Thereby, the heat dissipation module 100 may, for example, be attached to a contact surface of the heat-generating device via the lower surface 118 of the hollow housing 110 to conduct the thermal energy generated by the heat-generating device to the external environment by means of the high conduction characteristic of the hollow housing 110. In addition, the area of heat exchange is increased by means of the heat dissipation fins 120 so that the heat dissipation liquid 130 contained within the hollow housing 110 is able to lower the temperature of the hollow housing 110 and the heat-generating device. It needs to be noted that the invention does not limit on the types of the heat dissipation liquid 130 and materials of the hollow housing 110. The scope is claimed by the invention as long as the specific heat of the heat dissipation liquid 130 is substantially greater than or equal to 1 cal/g° C. and the thermal conductivity of the hollow housing 110 is substantially greater than or equal to 230 W/mK. In addition, the heat-generating device in this embodiment may be, for example, an LED chip. It is for sure that this embodiment is merely an example, and the invention does not limit on the types of the heat-generating device.

FIG. 2 is a schematic view of a heat dissipation module according to another embodiment of the invention. It should be noted herein that a heat dissipation module 100a in this embodiment is similar to the heat dissipation module 100 in FIG. 1, and therefore descriptions about this embodiment continues with reference to part of the contents in the previous embodiment, in which identical or similar reference numerals indicate identical or similar components, and repeated description of the same technical contents is omitted. For a detailed description of the omitted parts, reference can be found in the previous embodiment, and no description will be repeated in this embodiment. Descriptions as follows are provided for the difference between the heat dissipation module 100a in this embodiment and the heat dissipation module 100 of FIG. 1.

Referring to FIG. 2, in this embodiment, each of heat dissipation fins 120a of the heat dissipation module 100a may further include a bending portion 122. More specifically, each of the heat dissipation fins 120a is extended along a direction parallel to the bottom surface 118 of the hollow housing 110 and bended at the bending portion 122 to be extended toward the bottom surface 118. Thereby, when the heat dissipation module 100a is attached to a contact surface 12 of a heat-generating device 10 via the lower surface 118 of the hollow housing 110, heat generated by the heat-generating device 10, as shown by the arrows of dotted lines in FIG. 2, is thermally conducted along a conducting path formed by hollow housing 110 and the heat dissipation fins 120a from the bottom of the hollow housing 110, and the heat dissipation fins 120a increases a thermal exchange area of the heat dissipation module 100a, so as to improve the heat dissipation efficiency of the heat dissipation module 100a. In this embodiment, the heat-generating device 10 may be a LED chip. It is for sure that this embodiment is merely an example, and the invention does not limit on the types of the heat-generating device 10.

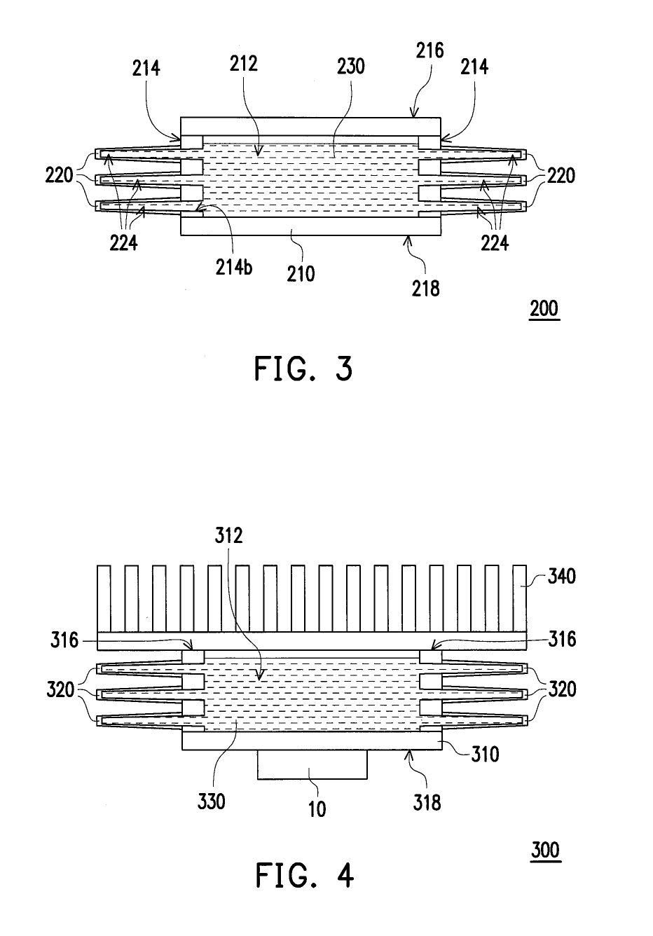

FIG. 3 is a schematic view of a heat dissipation module according to another embodiment of the invention. It should be noted herein that a heat dissipation module 200 in this embodiment is similar to the heat dissipation module 100 in FIG. 1, and therefore descriptions about this embodiment continues with reference to part of the contents in the previous embodiment, in which identical or similar reference numerals indicate identical or similar components, and repeated description of the same technical contents is omitted. For a detailed description of the omitted parts, reference can be found in the previous embodiment, and no description will be repeated in this embodiment. Descriptions as follows are provided for the difference between the heat dissipation module 200 in this embodiment and the heat dissipation module 100 of FIG. 1.

Referring to FIG. 3, in this embodiment, each of heat dissipation fins 220 of the heat dissipation module 200 is a hollow heat dissipation fin, namely, each heat dissipation fin 220 has a hollow portion 224. A chamber 212 connects the hollow portions 224, and heat dissipation liquid 230 is contained within the chamber 212 and the hollow portions 224 that connect to each other to increase a contact area of the heat dissipation liquid 230 with the hollow housing and the heat dissipation fins 220, so as to improve the heat dissipation efficiency of the heat dissipation module 200. More specifically, side walls of a hollow housing 210 may have a plurality of through holes 214a corresponding to the hollow portions 224 of the heat dissipation fins 220, so that the chamber 212 of the hollow housing 210 communicates with the hollow portions 224 of the heat dissipation fins 220. In this embodiment, the hollow housing 210 may be integrally formed with the heat dissipation fins 220. It is for sure that the invention is not limited thereto.

FIG. 4 is a schematic view of a heat dissipation module according to another embodiment of the invention. It should be noted herein that a heat dissipation module 300 in this embodiment is similar to the heat dissipation module 200 in FIG. 3, and therefore descriptions about this embodiment continues with reference to part of the contents in the previous embodiment, in which identical or similar reference numerals indicate identical or similar components, and repeated description of the same technical contents is omitted. For a detailed description of the omitted parts, reference can be found in the previous embodiment, and no description will be repeated in this embodiment. Descriptions as follows are provided for the difference between the heat dissipation module 300 in this embodiment and the heat dissipation module 200 of FIG. 3.

Referring to FIG. 4, in this embodiment, the heat dissipation module 300 may further include a heat dissipation fin set 340. If the heat dissipation module 300 is attached to the heat-generating device 10 via a lower surface 318 of a hollow housing 310, the heat dissipation fin set 340 may be disposed on an upper surface 316 of the hollow housing 310 and thermally coupled with the hollow housing 310, so that the heat dissipation module 300 further conducts the heat generated by the heat-generating device 10 to the external environment via the heat dissipation fin set 340. In addition, in this embodiment, the heat dissipation fin set 340 covers a chamber 312, namely, the heat dissipation fin set 340 is able to substitute for a top plate in the hollow housing 310 for covering the chamber 312. It is for sure that this embodiment is merely an example. In other embodiments of the invention, the hollow housing 310 may also, as shown in FIGS. 1 to 3, has a top plate for covering the chamber 312, while the heat dissipation fin set 340 is disposed on this top plate. The invention does not limit on the arrangement of the heat dissipation fin set 340, and the heat dissipation fin set 340 may be disposed on any hollow housing in FIGS. 1 to 3.

FIG. 5 is a schematic view of a heat dissipation module according to another embodiment of the invention. It should be noted herein that a heat dissipation module 400 in this embodiment is similar to the heat dissipation module 300 in FIG. 4, and therefore descriptions about this embodiment continues with reference to part of the contents in the previous embodiment, in which identical or similar reference numerals indicate identical or similar components, and repeated description of the same technical contents is omitted. For a detailed description of the omitted parts, reference can be found in the previous embodiment, and no description will be repeated in this embodiment. Descriptions as follows are provided for the difference between the heat dissipation module 400 in this embodiment and the heat dissipation module 300 of FIG. 4.

Referring to FIG. 5, in this embodiment, the heat dissipation module 400 may further include a vapor chamber 450, wherein the vapor chamber 450 may, for example, be disposed between a heat dissipation fin set 440 and a hollow housing 410 and be thermally coupled respectively with the heat dissipation fin set 440 and the hollow housing 410. More particularly, the vapor chamber 450 includes a vacuum chamber 452 and a phase-transition medium 454. An inner wall of the vacuum chamber 452 has a plurality of micro-structures 456. The phase-transition medium 454 is contained within the vacuum chamber 452 and is configured to perform liquid-gas phase transition in the vacuum chamber 452. It is for sure that the invention does not limit on the arrangement and position of the vapor chamber 450, and the vapor chamber 450 may be disposed on any hollow housing in FIGS. 1 to 4.

More specifically, the vapor chamber 450 may include a vaporization zone close to the heat-generating device 10 and a condensation zone away from the heat-generating device 10. In the initial state, the phase-transition medium 454 is in liquid phase. When heat generated by the heat-generating device 10 is conducted to the vaporization zone of the vapor chamber 450, the phase-transition medium 454 in the vacuum chamber 452 in an environment of low degree of vacuum goes through a phase transition from liquid phase to vapor. At this point, the phase-transition medium 454 in liquid phase absorbs thermal energy and transforms into phase-transition medium 454 in gas phase while the volume expands quickly, so that the phase-transition medium 454 in gas phase fills the whole chamber 452 soon. When the phase-transition medium 454 in gas phase contacts the condensation zone away from the heat-generating device 10 and having a lower temperature, the phenomenon of condensation occurs, and the phase-transition medium 454 in gas phase transforms into the phase-transition medium 454 in liquid phase. The condensed phase-transition medium 454 returns back to the vaporization zone by means of capillary phenomenon of the micro-structures 456. Such a cycle goes on and on within the vacuum chamber 452 to maintain the temperature uniformity of the vapor chamber 450, so that the heat dissipation module 400 is able to enhance heat dissipation efficiency thereof by means of the vapor chamber 450.

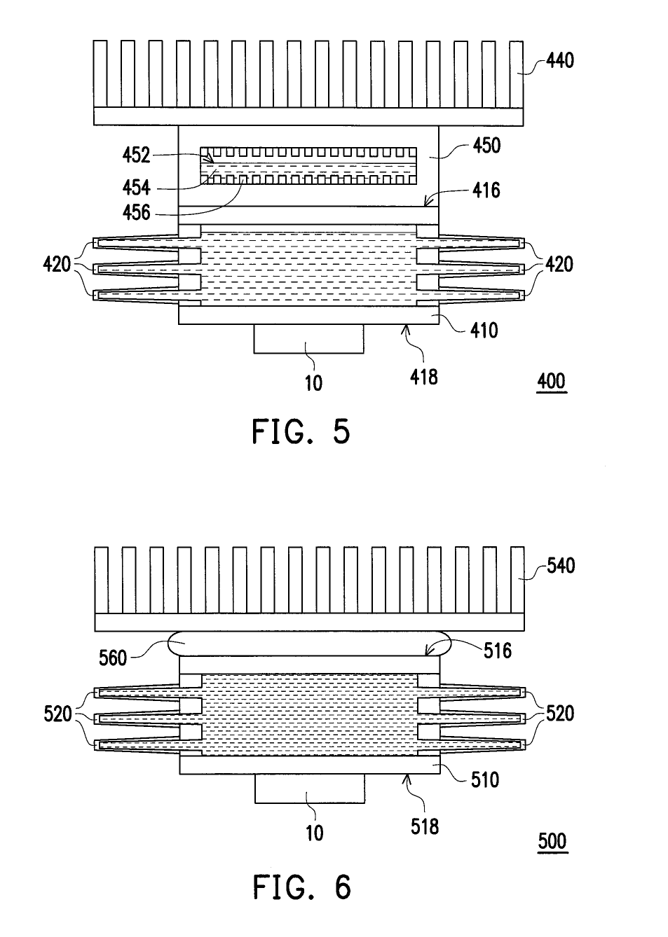

FIG. 6 is a schematic view of a heat dissipation module according to another embodiment of the invention. It should be noted herein that a heat dissipation module 500 in this embodiment is similar to the heat dissipation module 300 in FIG. 4, and therefore descriptions about this embodiment continues with reference to part of the contents in the previous embodiment, in which identical or similar reference numerals indicate identical or similar components, and repeated description of the same technical contents is omitted. For a detailed description of the omitted parts, reference can be found in the previous embodiment, and no description will be repeated in this embodiment. Descriptions as follows are provided for the difference between the heat dissipation module 500 in this embodiment and the heat dissipation module 300 of FIG. 4.

Referring to FIG. 6, in this embodiment, the heat dissipation module 500 may further include a heat pipe 560, wherein the heat pipe 560 may, for example, be disposed between a heat dissipation fin set 540 and a hollow housing 510 and be thermally coupled with the heat dissipation fin set 540 and the hollow housing 510. More specifically, the heat pipe 560 may include a hollow metal pipe so as to have the characteristic of light weight and excellent thermal conduction efficiency. A fluid may be contained within the hollow metal pipe. By means of phase transition of the fluid continuously cycling between liquid and gas within the hollow metal pipe, the heat pipe 560 is able to reach surface temperature uniformity quickly to fulfill the purpose of thermal conduction, so that heat dissipation efficiency of the heat dissipation module 500 is enhanced by means of the heat pipe 560. It is for sure that the invention does not limit on the arrangement and position of the heat pipe 560, and the heat pipe 560 may be disposed on any hollow housing in FIGS. 1 to 5.

In view of the above, the heat dissipation module of the invention has a hollow housing that is highly thermal conductive (having the thermal conductivity substantially greater than or equal to 230 W/mK) for containing the heat dissipation liquid having the high specific heat (which is substantially greater than or equal to 1 cal/g° C.), and a plurality of heat dissipation fins are disposed on the side surface of the hollow housing. Thereby, by attaching the heat dissipation module on the heat-generating device, the heat dissipation module conducts the thermal energy generated by the heat-generating device to the external environment by means of the high conduction characteristic of the hollow housing. In addition, the area of heat exchange is increased by means of the heat dissipation fins so that the heat dissipation liquid having high specific heat contained within the hollow housing is able to lower the temperature of the hollow housing and the heat-generating device. Therefore, the invention indeed has excellent heat dissipation effects. In addition, heat dissipation elements such as the heat dissipation fin set, the vapor chamber and/or the heat pipe may be additionally arranged in the heat dissipation module of the invention, so as to further enhance the heat dissipation efficiency of the heat dissipation module. Furthermore, any person having ordinary skills in the art is able to autonomously permute and combine the above elements according to the actual needs of the product, so as to achieve desired heat dissipation effects. Thus, the heat dissipation module of the invention meets a variety of needs and indeed improves the design of the heat dissipation module and the flexibility in use.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A heat dissipation module, comprising:
a hollow housing, comprising a chamber, a side surface, a top surface and a bottom surface opposite to the top surface, wherein the side surface is connected to the top surface and the bottom surface;
a plurality of heat dissipation fins, disposed on the side surface; and
heat dissipation liquid, contained within the chamber, and a specific heat of the heat dissipation liquid is substantially greater than or equal to 1 cal/g° C.

2. The heat dissipation module according to claim 1, wherein the chamber is a sealing chamber.

3. The heat dissipation module according to claim 1, wherein each of the heat dissipation fins is a hollow heat dissipation fin having a hollow portion, the chamber connects the hollow portions, and the heat dissipation liquid is contained within the chamber and the hollow portions.

4. The heat dissipation module according to claim 1, wherein a thermal conductivity of the hollow housing is greater than or equal to 230 W/mK.

5. The heat dissipation module according to claim 1, wherein the heat dissipation module is attached to a heat-generating device via the bottom surface.

6. The heat dissipation module according to claim 5, wherein each of the heat dissipation fins further comprises a bending portion, and each of the heat dissipation fins is extended along a direction parallel to the bottom surface and bended at the bending portion to be extended toward the bottom surface.

7. The heat dissipation module according to claim 5, further comprising a heat dissipation fin set that is disposed on the top surface and thermally coupled with the hollow housing.

8. The heat dissipation module according to claim 7, wherein the heat dissipation fin set covers the chamber.

9. The heat dissipation module according to claim 7, further comprising a vapor chamber disposed between the heat dissipation fin set and the hollow housing and thermally coupled therewith, wherein the vapor chamber comprises a vacuum chamber and a phase-transition medium, an inner wall of the vacuum chamber has a plurality of micro-structures, and the phase-transition medium is contained within the vacuum chamber and is configured to perform liquid-gas phase transition in the vacuum chamber.

10. The heat dissipation module according to claim 7, further comprising a heat pipe disposed between the heat dissipation fin set and the hollow housing and thermally coupled therewith.
